(19) United States
(12) Patent Application Publication
(10) Pub. No.: US 2022/0230842 A1
(43) Pub. Date: Jul. 21, 2022

(54) PATTERN MEASUREMENT SYSTEM AND PATTERN MEASUREMENT METHOD

(71) Applicant: Hitachi High-Tech Corporation, Tokyo (JP)

(72) Inventors: Wei SUN, Tokyo (JP); Takuma YAMAMOTO, Tokyo (JP); Yasunori GOTO, Tokyo (JP)

(73) Assignee: Hitachi High-Tech Corporation, Tokyo (JP)

(21) Appl. No.: 17/609,198

(22) PCT Filed: May 8, 2019
(86) PCT No.: PCT/JP2019/018421

§ 371 Date: Nov. 5, 2021

(51) Int. Cl. H01J 37/244; H01J 37/28

(52) U.S. Cl. CPC H01J 37/244; H01J 37/28; H01J 2237/2804; H01J 2237/221; H01J 2237/2814; H01J 2237/2806; H01J 2237/2817

(57) ABSTRACT

In order to measure a 3D profile of a pattern formed on a sample obtained by stacking a plurality of different materials, for each of materials constituting the pattern, an attenuation coefficient μ indicating a probability of an electron being scattered at a unit distance in the material previously stored, an interface position where different materials are in contact, upper and bottom surface positions of the pattern in a BSE image are extracted, and a depth from the upper surface position to a specified position of the pattern is calculated based on a ratio nIh of a contrast between the specified position and the bottom surface position of the pattern to a contrast between the upper and bottom surface positions of the pattern in the BSE image, an attenuation coefficient of a material at the bottom and specified positions of the pattern.

### TECHNICAL FIELD

The present invention relates to a pattern measurement system and a pattern measurement method of measuring a 3D profile of a pattern formed on a semiconductor wafer or the like.

### BACKGROUND ART

In order to increase capacity of memory devices and reduce bit costs, process shrinkage and high-level integration of semiconductor devices have been progressed so far. In recent years, in order to meet a demand for higher integration, the development and manufacture of 3D structured devices have been developed. When a planar structure is made to be three-dimensional, the device becomes thicker. For example, 3D-NAND and DRAM, the number of the stacked film layers increases. Therefore, in the process the ratio of the depth to the area in horizontal plane (aspect ratio) of a hole or a trench increases. In addition, the kinds of materials used in the device also tend to increase.

For example, in order to etch a very high aspect ratio hole or trench having a diameter of 50 nm to 100 nm and a depth of 3 pm or more, firstly, it is necessary to open a thick mask using a material with high selectivity. This is a process to make a template that guides a subsequent etching step, and the requirement for the process accuracy is extremely high. Subsequently, the etched mask is used as a template to perform etching to form the hole or the trench by dividing a stacked film made of different materials into one or more parts. When etching is performed in a state where a wall surface penetrating the mask or stacked film of different materials is not perpendicular to a surface, stable device performance may not be finally obtained. Therefore, confirmation of the shape of the hole of trench during and after an etching process is very important.

In order to know the 3D profile of the pattern, it is possible to obtain an accurate cross-sectional shape by cutting the wafer and measuring the cross-sectional shape. However, it takes time and cost to check wafer-level uniformity. Therefore, a nondestructive method of accurately measuring, in a method for measuring the dimension, the cross-sectional profile, or a 3D profile at a desired height of a pattern formed on different materials is desired.

Here, a general method using microscopes such as an electron microscope to observe a 3D profile without breaking a wafer includes two methods: stereo observation and top-down observation.

For example, in stereo observation described in PTL 1, the tilt angle of an electron beam relative to the surface of the sample is changed by inclining a sample stage or the electron beam, and measurement such as a height of a pattern and an sidewall angle of a side wall is performed by using a plurality of images obtained by different incident angles.

In addition, when the aspect ratio of a deep hole or a trench increases, efficiency of detecting secondary electrons emitted from a bottom decreases, and therefore, PTL 2 describes a method of measuring the depth of the hole by detecting a backscattered electron (BSE) generated by a high-energy primary electron, and using a phenomenon that the amount of BSE signals decreases with increasing the depth of the hole.

### CITATION LIST

### Patent Literature

PTL 1: JP-T-2003-517199

PTL 2: JP-A-2015-106530

### SUMMARY OF INVENTION

### Technical Problem

In an etching step of a pattern having a high aspect ratio, it is difficult to control the shape of the side wall or the bottom. The change of dimension at the interface of different materials, taper, bowing, and twisting may appear. Therefore, not only a dimension of an upper surface or a bottom surface of the hole or the trench, but also a cross-sectional profile is an important evaluation item. In addition, since the wafer -level uniformity is required at a high accuracy level, it can be said that the key to improving a yield is to inspect and measure a wafer-level variation and to give a feedback to a device manufacturing process (for example, etching tool).

However, in PTL 1, measurement from a plurality of angles is indispensable, and there are problems such as an increase in measurement time and complexity of an analysis method. Moreover, since only information on edges (ends) of the pattern can be obtained, measurement of a continuous 3D profile cannot be performed.

In addition, PTL 2 discloses that based on a standard sample or actual measurement data with known hole depth, the depth of the bottom of the hole is measured by using a phenomenon that an absolute signal amount of transmitted backscattered electrons decreases when a hole bottom is deep. However, an intensity of a backscattered electron signal detected from a hole formed in different materials is influenced by both continuous 3D profile information inside the hole (a height to an upper surface of the pattern) and material information (the intensity of the backscattered electron signal depending on the material). Therefore, in order to obtain the depth information and a three-dimensional profile based on the intensity of the backscattered electron signal, it is not possible to measure a highly accurate cross-sectional shape or a three-dimensional shape unless these two information are separated. PTL 2 does not explain separation of the two information.

### Solution to Problem

A pattern measurement system which is an embodiment of the invention is a pattern measurement system configured to measure a 3D profile of a pattern formed on a sample obtained by stacking a plurality of different materials, and includes: a storage unit configured to store, for each of these materials constituting the pattern, an attenuation coefficient indicating a probability of an electron being scattered at a unit distance in the material; and a calculation unit configured to extract an interface position where different materials are in contact with each other, an upper surface position, and a bottom surface position of the pattern in a BSE image created by detecting a backscattered electron emitted by scanning the pattern with a primary electron beam, and calculate a depth from the upper surface position to a specified position of the pattern, in which the calculation unit calculates the depth from the upper surface position to the specified position of the pattern based on a ratio of a contrast between the specified position and the bottom surface position of the pattern to a contrast between the upper surface position and the bottom surface position of the pattern in the BSE image, and an attenuation coefficient of a material at the bottom surface position of the pattern and an attenuation coefficient of a material at the specified position of the pattern, which are stored in the storage unit.

A pattern measurement system which is another embodiment of the invention is a pattern measurement system configured to measure a 3D profile of a pattern formed on a sample obtained by stacking a plurality of different materials, and includes: an electron optical system configured to irradiate the sample with a primary electron beam; a first electron detector configured to detect a secondary electron emitted by scanning the pattern with the primary electron beam; a second electron detector configured to detect a backscattered electron emitted by scanning the pattern with the primary electron beam; an image processing unit configured to form an image based on a detection signal of the first electron detector or the second electron detector; and a calculation unit configured to compare a cross-section profile of a side wall of the pattern extracted from a cross-sectional image of the pattern and a BSE profile which indicates a backscattered electron signal intensity from the side wall of the pattern along a predetermined direction and which is extracted from a BSE image formed by the image processing unit based on the detection signal of the second electron detector, distinguish the BSE profile according to the pattern formed in each of the materials, and obtain an attenuation coefficient of the material based on a relationship between a depth from an upper surface position of the pattern and a backscattered electron signal intensity in the distinguished BSE profile.

A pattern measurement method which is yet another embodiment of the invention is a pattern measurement method of measuring a 3D profile of a pattern formed on a sample obtained by stacking a plurality of different materials, and includes: previously storing, for each of materials constituting the pattern, an attenuation coefficient indicating a probability that the material and an electron are scattered at a unit distance in the material; and extracting an interface position where different materials are in contact with each other, an upper surface position, and a bottom surface position of the pattern in a BSE image created by detecting a backscattered electron emitted by scanning the pattern with a primary electron beam; and calculating a depth from the upper surface position to a specified position of the pattern based on a ratio of a contrast between the specified position and the bottom surface position of the pattern to a contrast between the upper surface position and the bottom surface position of the pattern in the BSE image, an attenuation coefficient of a material at the bottom surface position of the pattern, and an attenuation coefficient of a material at the specified position of the pattern.

### Advantageous Effect

It is possible to accurately measure a cross-sectional shape or a 3D profile of a 3D structure such as a deep hole or a deep trench formed in different materials.

Other problems and novel features will become clear from the description of the present specification and the accompanying drawings.

### BRIEF DESCRIPTION OF DRAWINGS

FIG. 1 is a schematic configuration diagram of a pattern measurement system.

FIG. 2 is a diagram illustrating a principle of measuring a 3D profile of a pattern.

FIG. 3 is a flowchart showing a sequence of measuring the 3D profile of the pattern.

FIG. 4 is an example of a GUI.

FIG. 5A is a diagram illustrating a method of estimating an attenuation coefficient μ using a cross-sectional image.

FIG. 5B is a diagram illustrating the method of estimating the attenuation coefficient μ using the cross-sectional image.

FIG. 5C is a diagram illustrating the method of estimating the attenuation coefficient μ using the cross-sectional image.

FIG. 6A is a diagram illustrating a method of estimating the attenuation coefficient μ using material information.

FIG. 6B is a diagram illustrating the method of estimating the attenuation coefficient μ using the material information.

FIG. 7A is an example (schematic diagram) of a BSE differential signal waveform (dI/dX).

FIG. 7B is a diagram illustrating a method of calculating an interface depth and a dimension.

FIG. 8A is an example of a GUI.

FIG. 8B is an example of an output screen of a 3D profile measurement result.

FIG. 8C is an example of the output screen of the 3D profile measurement result.

FIG. 9A is a flowchart of an SEM showing a sequence of measuring the 3D profile of the pattern offline.

FIG. 9B is a flowchart of a calculation server showing the sequence of measuring the 3D profile of the pattern offline.

FIG. 10A is an example of a pattern formed on a sample obtained by stacking a plurality of materials.

FIG. 10B is an example of a pattern formed on a sample obtained by periodically stacking a plurality of materials.

### DESCRIPTION OF EMBODIMENTS

Hereinafter, a measurement system and a measurement method of measuring a cross-sectional shape or a 3D profile of a hole pattern or a trench pattern having a high aspect ratio formed in a stack made of different materials in observation or measurement of a semiconductor wafer or the like in a semiconductor manufacturing process will be described. An example of a sample to be observed is a semiconductor wafer on which a pattern is formed, but the sample is not limited to a pattern on a semiconductor and any sample that can be observed by an electron microscope or other microscopes can be applicable.

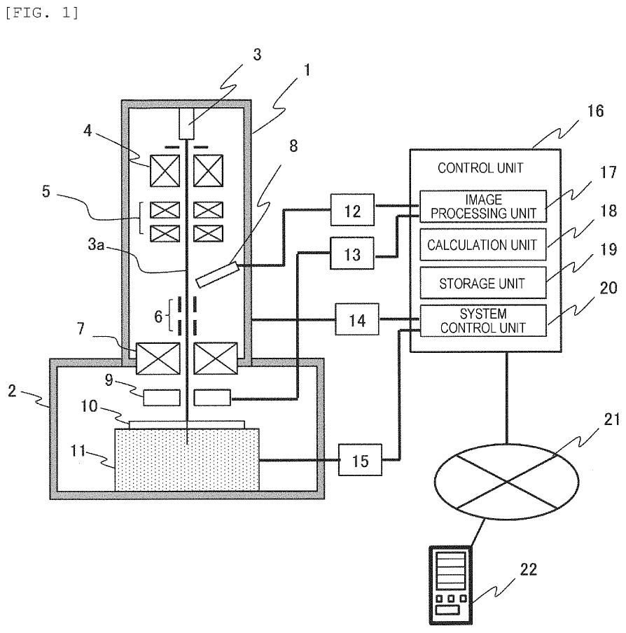

FIG. 1 shows a pattern measurement system of the present embodiment. An example of using a scanning electron microscope (SEM) is shown as one embodiment of the pattern measurement system. A scanning electron microscope main body is composed of an electron optical column 1 and a sample chamber 2. As main components of an electron optical system, an electron gun 3, which generates an electron and is an emission source of a primary electron beam energized with a predetermined acceleration voltage, a condenser lens 4 configured to focus an electron beam, a deflector 6 configured to scan a wafer (sample) 10 with the primary electron beam, and an objective lens 7 configured to focus the primary electron beam and irradiate the sample are provided inside the column 1. In addition, a deflector 5 that deviates the primary electron beam from an ideal optical axis 3a and deflects the deviated beam in a direction inclined with respect to the ideal optical axis 3a to obtain an inclined beam is provided. These optical elements constituting the electron optical system are controlled by an electron optical system control unit 14. The wafer 10, which is a sample, is placed on an XY stage 11 installed in the sample chamber 2, and the wafer 10 is moved according to a control signal provided by a stage control unit 15. A system control unit 20 of a control unit 16 scans an observation region of the wafer 10 with the primary electron beam by controlling the electron optical system control unit 14 and the stage control unit 15.

In the present embodiment, in order to measure a 3D profile of a deep hole or a deep trench having a high aspect ratio, the wafer 10 is irradiated with a high-energy (high acceleration voltage) primary electron beam that can reach a deep part of the pattern. The electron generated by scanning the wafer 10 with the primary electron beam is detected by a first electron detector 8 and a second electron detector 9. Detection signals output from the detectors are separately signal-converted by an amplifier 12 and an amplifier 13, and are input to an image processing unit 17 of the control unit 16.

The first electron detector 8 mainly detects a secondary electron generated by irradiating the sample with the primary electron beam. The secondary electron is an electron excited from an atom constituting the sample by inelastically scattering a primary electron in the sample, and energy thereof is 50 eV or less. Since an emission amount of the secondary electron is sensitive to a surface shape of a sample surface, the detection signal of the first electron detector 8 mainly indicates pattern information of a wafer surface (upper surface). On the other hand, the second electron detector 9 detects a backscattered electron generated by irradiating the sample with the primary electron beam. The backscattered electron (BSE) is obtained by emitting the primary electron, with which the sample is irradiated, from the sample surface in the process of scattering the primary electron. When a flat sample is irradiated with the primary electron beam, a BSE emission rate mainly reflects material information.

The control unit 16 includes an input unit (not shown) and a display unit (not shown), and information necessary for measuring the 3D profile is input and the information is stored in a storage unit 19. As will be described in detail later, cross-section information about a measurement target pattern, a material information database about materials constituting the measurement target pattern, and the like are stored in the storage unit 19. In addition, an image output from the image processing unit 17 is also stored in the storage unit 19.

As will be described in detail later, a calculation unit 18 computes an attenuation coefficient, which is a parameter for measuring a 3D profile pattern of the measurement target pattern using an image captured by the SEM (BSE image, secondary electron image) and the cross-section information about the measurement target pattern, and calculates a depth and a dimension of the measurement target pattern.

Although the pattern measurement system of the present embodiment can construct a three-dimensional model of a pattern, since the construction of the three-dimensional model requires high processing capability of a computer, a calculation server 22 connected to the control unit 16 via a network 21 may be provided. This enables quick three-dimensional model construction after image acquisition. Providing the calculation server 22 is not limited to the purpose of constructing a three-dimensional model. For example, when pattern measurement is performed offline, computation resources of the control unit 16 can be effectively used by causing the calculation server 22 to perform computation processing in the control unit 16. In this case, more efficient operation becomes possible by connecting a plurality of SEMs to the network 21.

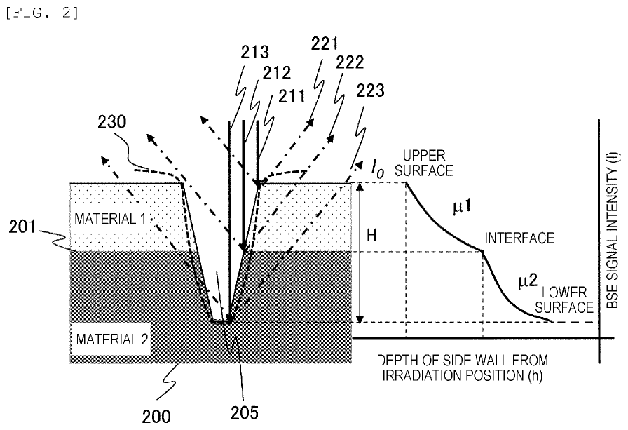

A principle of measuring the 3D profile of the pattern in the present embodiment will be described with reference to FIG. 2. A measurement target in this embodiment is a hole pattern provided at a predetermined density in a sample 200 in which two kinds of materials having different average atomic numbers are stacked. For the sake of clarity, the figure shows only one hole pattern and a shape of the hole pattern is exaggerated.

In pattern shape measurement of the present embodiment, when a side wall of the hole 205 is irradiated with the primary electron beam, an electron is scattered inside the sample, and a BSE that has passed through the sample surface and jumped out is detected. When the pattern is a deep hole or a deep trench having a depth of 3 μm or more, such as 3D-NAND or DRAM, the acceleration voltage of the primary electron beam is 5 kV or more, and preferably 30 kV or more. FIG. 2 schematically shows a state where a BSE 221 is emitted with respect to a primary electron beam 211 emitted on the sample surface (the upper surface of the pattern), a state where a BSE 222 is emitted with respect to a primary electron beam 212 emitted on an interface 201 between a material 1 and a material 2, and a state where a BSE 223 is emitted with respect to a primary electron beam 213 emitted on a bottom surface of the hole 205.

Here, a volume of a hole or a trench having a high aspect ratio, which is a cavity formed in the sample 200, is much smaller than that in an electron scattering region in the sample, and an influence on an electron scattering trajectory is extremely small. In addition, it has been found that the primary electron beam is incident on an inclined side wall of the hole 205 at a predetermined incident angle, but when the primary electron beam has high acceleration and a small incident angle, an influence of a difference in incident angle on the electron scattering trajectory is negligible.

Further, it is known that the hole 205 is formed in a sample obtained by stacking different materials, and an amount of BSE generated depends on average atomic numbers of the materials.

That is, a BSE signal intensity 230 obtained by scanning the hole 205 with the primary electron beam depends on an average distance from an incident position of the primary electron beam to a surface, and also depends on an average atomic number of materials in the electron scattering region. A magnitude of a BSE signal intensity I can be expressed by (Equation 1).

### [Math. 1]

I=I₀e^{-μh} (Equation 1)

Here, an initial BSE signal intensity Io is a BSE signal intensity generated at an irradiation position of the primary electron beam, and depends on the acceleration voltage of the primary electron beam, that is, the energy of the primary electron. An attenuation coefficient μ is a physical quantity that indicates a speed of attenuation, and indicates a probability that an electron and a solid material are scattered at a unit distance through which the electron passes. The attenuation coefficient μ has a value that depends on the material. A passing distance h is a depth from the sample surface (the upper surface of the pattern) to the irradiation position of the primary electron beam.

The detected BSE signal intensity I can be expressed as a function of an average distance h from the irradiation position of the primary electron beam to the sample surface, and the attenuation coefficient μ in this way. That is, as the irradiation position of the primary electron beam approaches the bottom surface of the hole, a distance that the electron passes through the solid becomes longer, and therefore, an energy loss increases and the BSE signal intensity decreases. In addition, a degree to which the BSE signal intensity decreases depends on materials constituting the sample. This is because for the two kinds of materials constituting the sample 200, when the material 2 has more atoms per unit volume than the material 1, a scattering probability of the material 2 is greater than a scattering probability of the material 1 and the energy loss also increases. In this case, there is a relationship of μ₁<μ₂ between an attenuation coefficient μ₁ of the material 1 and an attenuation coefficient μ₂ of the material 2.

In other words, the detected BSE signal intensity I includes both information about a depth position at which the BSE is emitted and information about a material in the electron scattering region. Therefore, it is possible to accurately calculate depth information (stereoscopic information) of the pattern by acquiring in advance the attenuation coefficient μ for each of the materials constituting the hole pattern or the trench pattern, which is the measurement target, to remove an influence of the difference in materials included in the BSE signal intensity obtained by scanning these patterns with the primary electron beam.

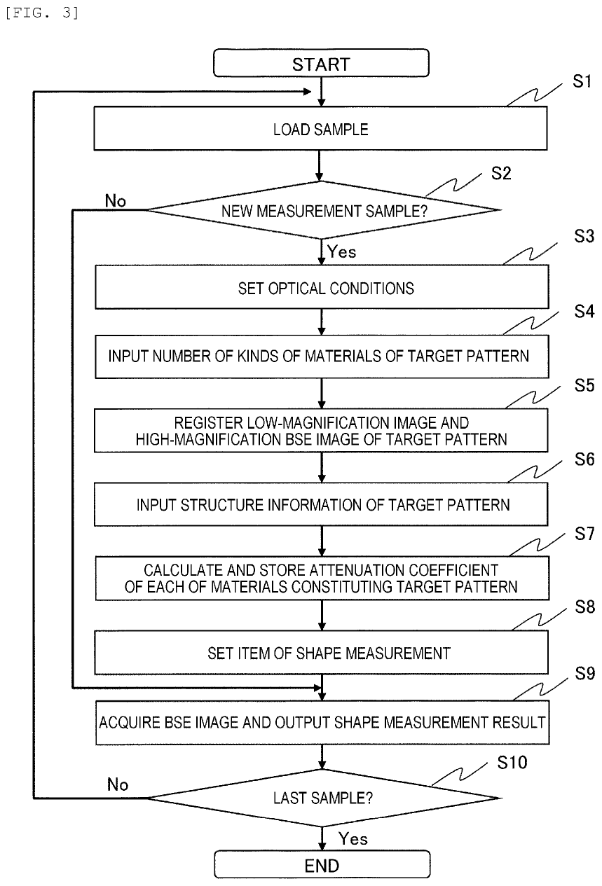

FIG. 3 is a sequence of measuring the 3D profile of the pattern using the pattern measurement system of the present embodiment. Firstly, the wafer on which the pattern, which is the measurement target, is formed is introduced into the sample chamber of the SEM (step S1). Next, it is determined whether the pattern, which is the measurement target, is a new sample for which measurement conditions need to be set (step S2). In the case of a sample whose pattern can be measured according to an existing measurement recipe, the 3D profile is measured according to the measurement recipe and a measurement result is output (step S9). In the case of a sample without a measurement recipe, firstly, appropriate optical conditions (acceleration voltage, beam current, beam aperture angle, etc.) are set to image the pattern (step S3). Next, the number of the kinds of materials constituting the measurement target pattern is input using a GUI (step S4). Imaging conditions for each of a low-magnification image and a high-magnification BSE image of the measurement target pattern are set, and the images are acquired and registered (step S5). Then, structure information of the measurement target pattern is input using the GUI (step S6). It is desirable to use a cross-sectional image of the measurement target pattern, but considering that such a cross-sectional image may not always be available, a plurality of structure information input methods are provided. Based on the input structure information, the attenuation coefficient μ of each of the materials constituting the target pattern is calculated and stored (step S7). Subsequently, a measurement item of a three-dimensional pattern to be measured is set (step S8). By the steps mentioned above, the measurement recipe for measuring the 3D profile of the pattern is ready.

The 3D profile is measured according to the measurement recipe, and a result of measuring the shape is output (step S9). Then, it is determined whether the sample is the last sample (step S10), and if the sample is not the last sample, the sequence returns to step S1 and measurement of the next sample is started. If the sample is the last sample in step S10, the measurement ends.

FIG. 4 is an example of a GUI 400 for executing the sequence shown in FIG. 3. The GUI 400 has two parts including an optical condition input unit 401 and a measurement target pattern registration (Registration of target pattern) unit 402.

Firstly, in setting the optical conditions (step S3), the optical condition input unit 401 is used to set an optical condition currently set (Current) or an optical condition number (SEM condition No) appropriate for imaging the measurement target pattern. A plurality of optical conditions (a combination of acceleration voltage, beam current, beam aperture angle, etc.) for imaging the pattern are stored in the SEM in advance, and a user can set the optical conditions by specifying any one of the optical conditions.

Subsequently, the user uses the measurement target pattern registration unit 402 to register the measurement target pattern. Firstly, the number of the kinds of materials constituting the measurement target pattern is input to a material constituent input unit 403 (step S4). In this example, “two kinds” is selected.

Subsequently, each of the low-magnification image and the high-magnification BSE image is registered as the image of the measurement target pattern (step S5). A top-view image registration unit 404 includes a low-magnification image registration unit 405 and a high-magnification BSE image registration unit 408. Firstly, the low-magnification image registration unit 405 specifies that the measurement target pattern is arranged in a center of a field of view by an imaging condition selection box 406, and a low-magnification image 407 is imaged and registered. It is desirable that the low-magnification image 407 is a secondary electron image suitable for observing the shape of the sample surface. In addition, it is desirable to set an imaging field of view wider than a scattering region of the primary electron beam according to the acceleration voltage set in the optical conditions. For example, when measuring a periodic pattern formed on a material SiO₂, the field of view is set to 5 μm×5 μm or more. Subsequently, the high-magnification BSE image registration unit 408 specifies that the measurement target pattern is arranged in the center of the field of view by an imaging condition selection box 409, and a high-magnification BSE image 410 is imaged and registered. For example, the imaging conditions selected by the imaging condition selection box 409 include focus, scan mode, incident angle of a primary beam, and the like.

Subsequently, the structure information of the measurement target pattern is input using a structure input unit 411 (step S6). As described above, a plurality of input methods for the structure information of the measurement target pattern are provided, and the user selects one of the input methods for input.

A first method is a method of inputting the cross-sectional image. For example, the user images a cross-sectional structure of the target pattern in advance by using SEM, FIB-SEM (focused ion beam microscope), STEM (scanning transmission electron microscope), AFM (atomic force microscope), etc., and registers the cross-sectional image from a cross-sectional image input unit 412. A second method is a method of inputting design data. The design data of a device (CAD drawing) is registered from a design data input unit 413. Alternatively, a file that stores the cross-sectional shape of the device maybe used, which is neither of the two methods. In this case, the file is read from a cross-section information input unit 414.

On the other hand, when it is not possible to input an image including the cross-sectional structure and a cross-sectional image such as the design data, a manual input unit 415 sequentially specifies the kind of a material and film thickness at a region including an upper surface to a lower surface of the target pattern. The manual input unit 415 is provided with a layer-based input box 416, so that material information for each layer constituting the target pattern can be input. The material information database of the material is provided in advance, and a material selection unit 417 selects a material constituting a layer, so that physical parameters of the material are automatically input from the material information database. When it is desired to actually measure and use the physical parameters of the material, the physical parameters are individually input from a user definition unit 418. The physical parameters required for input are physical parameters required to calculate the average atomic number of the material of the layer. In addition, the film thickness of the layer is input from a film thickness input unit 419.

The attenuation coefficient μ for each layer is estimated and stored based on the input structure information of the measurement target pattern, and is displayed on an attenuation coefficient display unit 420 (step S7). Hereinafter, a method of estimating the attenuation coefficient μ will be described.

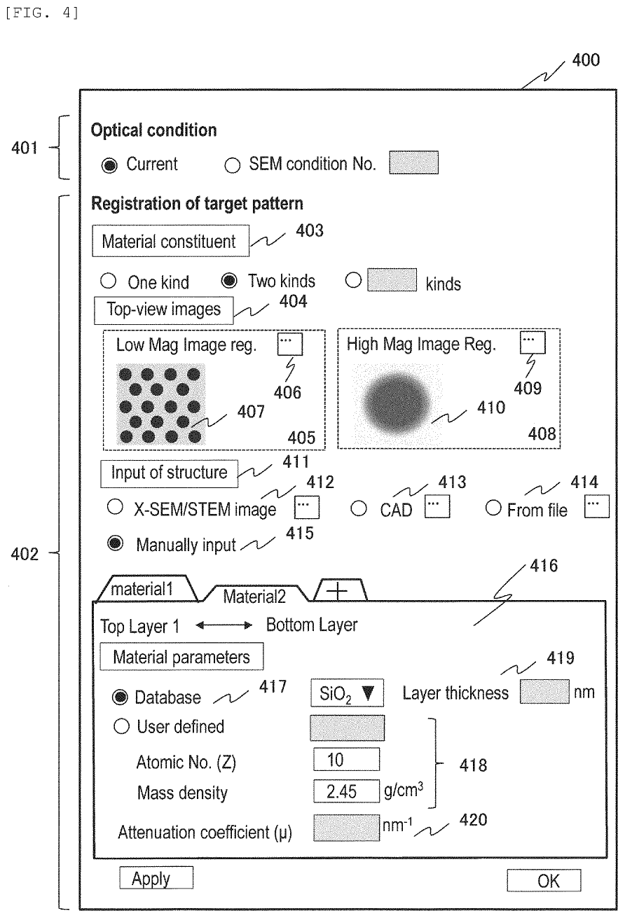

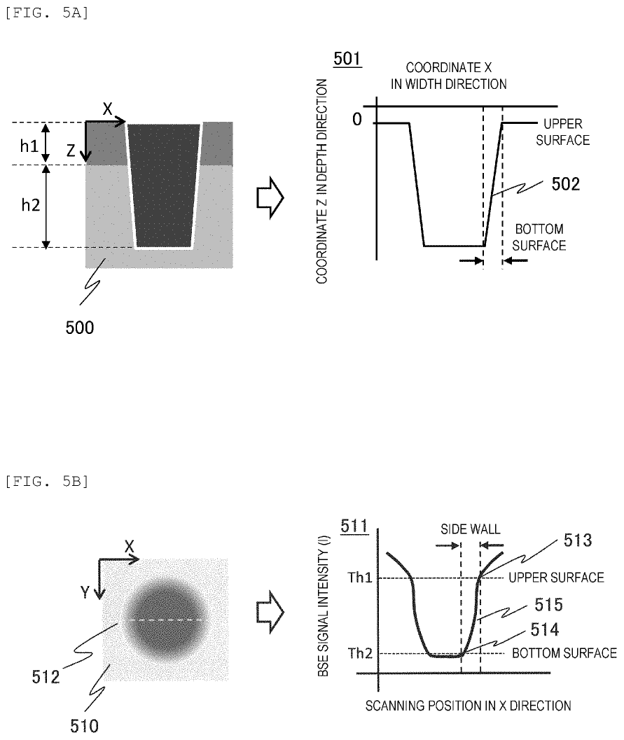

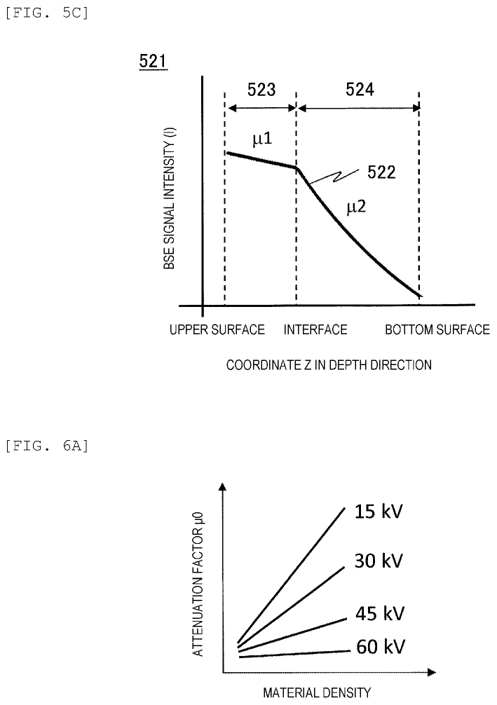

The method of estimating the attenuation coefficient μ when a cross-sectional image is input as the structure information of the measurement target pattern will be described with reference to FIGS. 5A to 5C. Firstly, as shown in FIG. 5A, a cross-section profile 501 of the measurement target pattern is acquired from a cross-sectional image 500. A cross-section profile of the measurement target pattern is data obtained by representing a cross section of the pattern by coordinates (X, Z) when a width direction of the pattern is an X-axis and a depth direction perpendicular to the upper surface of the pattern is a Z-axis. The cross-section profile can be obtained by using, as a contour extraction method, a well-known method such as signal differential processing or processing by a high-pass filter. In the case of a two-dimensional image, a high-level differentiation may be used so as to react sharply to an edge. Left and right inclined portions 502 in the cross-section profile 501 are side walls of the measurement target pattern. The coordinates (X, Z) between the upper surface of the pattern and the bottom surface of the pattern corresponding to cross-section profiles of the side walls (inclined portions 502) of the measurement target pattern are extracted. The coordinates (X, Z) corresponding to the side walls of the measurement target pattern may be extracted by using a machine learning model.

Next, as shown in FIG. 5B, a BSE profile 511 of the measurement target pattern is acquired from a high-magnification BSE image 510 along a specified orientation 512. A BSE profile of the measurement target pattern is data obtained by representing a BSE signal intensity (X, I) along a certain direction with coordinates of a specified orientation (as an X-axis) on the horizontal axis and a BSE signal intensity I on the vertical axis. Positions of an upper surface and a bottom surface of a hole in the BSE profile 511 are determined. A first threshold value Th1 for determining an upper surface position of the pattern and a second threshold value Th2 for determining a bottom surface position of the pattern are set for the BSE profile 511. The threshold values are set such that a variation of the BSE signal intensity I due to noise is minimized. For example, the first threshold value Th1 is set as 90% of the total height of a signal waveform in the BSE profile 511, and the second threshold value Th2 is set as 0% of the total height of the signal waveform. It should be noted that the above-mentioned values of the threshold values are examples.

If a high-magnification secondary electron image is acquired at the same time as the high-magnification BSE image 510 is acquired, it is desirable to determine the upper surface position by using the high-magnification secondary electron image. Since the edges of the pattern appear in high contrast in the secondary electron image, the upper surface position can be determined with higher accuracy. Therefore, in step S5 (see FIG. 3) or step S9, it is desirable to simultaneously acquire the BSE image generated based on a signal detected by the second electron detector 9 and the secondary electron image generated based on a signal detected by the first electron detector 8. When positions of the upper surface and the bottom surface of the pattern are determined in the BSE profile 511 in this way, a BSE signal waveform 515 between an upper surface position 513 and a bottom surface position 514, that is, between the side walls of the measurement target pattern is extracted.

Subsequently, the side wall coordinates (X, Z) extracted from the cross-section profile 501 and the BSE signal waveform (X, I) of the side wall extracted from the BSE profile 511 are used to create a BSE profile 521 with the X coordinate as a key, the Z coordinate on the horizontal axis, and the BSE signal intensity I on the vertical axis. The BSE profile 521 (schematic diagram) thus obtained is shown in FIG. 5C. At this time, since a pixel size in an X direction of the cross-sectional image 500 and a pixel size in an X direction of the high-magnification BSE image 510 are usually different from each other, it is necessary to adjust these pixel sizes such that these pixel sizes have the same size. For example, when a pixel size of the cross-section profile 501 is large, the data may be increased and matched by an interpolation method.

The BSE profile 521 has the depth direction on the horizontal axis and the BSE signal intensity on the vertical axis, and a BSE signal waveform 522 has a portion having different slopes depending on the material. Therefore, the attenuation coefficient μ of each material is calculated by classifying the BSE signal waveform in a range 523 from the upper surface to the interface and the BSE signal waveform in a range 524 from the bottom surface to the interface and fitting each BSE signal waveform to (Equation 1), and the calculated attenuation coefficient μ is stored. It should be noted that FIG. 5C is a schematic diagram, and in practice, there is a possibility that a clear inflection point as shown in FIG. 5C cannot be seen near the interface due to the influence of a plurality of material layers included in a BSE scattering region. Therefore, weighting of data near the interface may be lowered upon fitting.

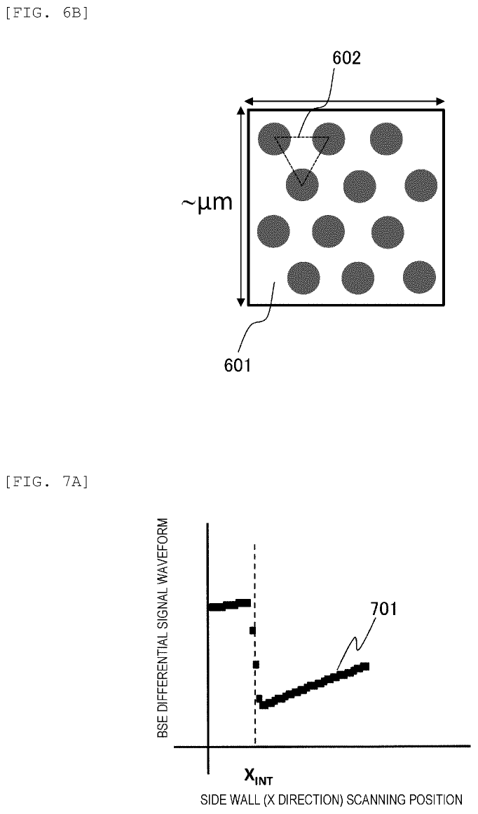

Next, a method of estimating the attenuation coefficient μ when the structure information of the measurement target pattern is manually input will be described with reference to FIGS. 6A and 6B. In this case, for a material often used in a semiconductor device in advance, a material density and an attenuation factor p0 at each acceleration voltage are calculated in advance by Monte Carlo simulation and are stored in a database. The calculation is made on the material as a single layer with no pattern formed. FIG. 6A schematically shows a relationship between the material density and the attenuation factor μ0 when the acceleration voltage is 15 kV, 30 kV, 45 kV, 60 kV for a certain material. The attenuation factor μ0 may be stored as a table or as a relational expression.

The device to be measured is a device in which a pattern such as a deep hole or a deep trench is periodically formed on a stack made of different materials. The densely formed pattern influences the scattering of an electron, that is, the detected BSE signal intensity, by reducing the material density. Therefore, when the “pattern density” is defined as a ratio of an opening area of a pattern (for example, a deep hole or a deep trench) to the minimum unit area in the periodically formed pattern, it can be said that as the pattern density increases, an average density of the sample decreases due to an increase in a vacuum portion in the material. Even under the same passing distance of the scattered electron, the energy loss due to scattering with a material atom is reduced, so that the detected BSE signal intensity is increased. That is, the attenuation coefficient μ and the average density of the material are in inverse proportional relation to each other.

Using this relation, the pattern density is calculated based on the low-magnification image 407 of the registered measurement target pattern, and the average density of the material of each layer constituting the sample can be calculated based on the density of the material in the case of no pattern and the pattern density of the sample. FIG. 6B is a binarized image 601 (schematic diagram) of the low-magnification image 407. A pixel value of the sample surface is set as 1, and a pixel value of an opening of a hole, which is a pattern, is set as 0. The pattern density is calculated by defining an individual unit 602 of a periodic pattern (defining the individual unit such that the periodic pattern is formed by being covered with the individual unit 602) for the binarized image 601 and calculating a ratio of the pixel having a pixel value of 0 to pixels of the entire individual unit 602.

By the above procedure, the user can obtain the attenuation coefficient μ of the material for each layer constituting the pattern regardless of whether the structure information of the measurement target pattern is input as a cross-sectional image or is manually input.

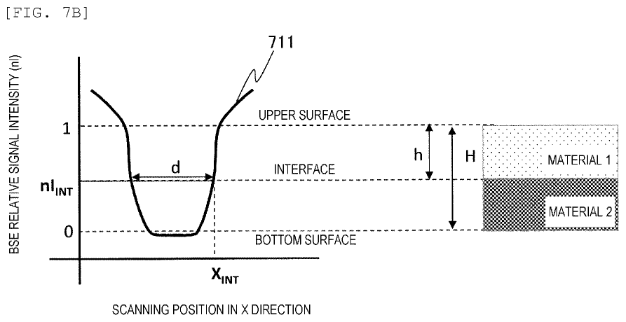

A method of measuring the depth information (3D profile) of the pattern by using the attenuation coefficient μ of each material constituting the measurement target pattern will be described. Firstly, the BSE profile is acquired from the BSE image of the pattern formed on the sample which is the measurement target, and the positions of the upper surface and the bottom surface of the hole in the BSE profile are determined. A method of determining the positions of the upper surface and the bottom surface of the hole in the BSE profile is the same processing as described with reference to FIG. 5B in the creation of the measurement recipe, and the duplicated explanation will be omitted. When the upper surface position and the bottom surface position are determined, the BSE signal waveform (X, I) between the upper surface position and the bottom surface position, that is, between the side walls of the measurement target pattern is obtained, and the BSE signal waveform (X, I) is differentiated. FIG. 7A shows an example (schematic diagram) of a BSE differential signal waveform (dI/dX) 701 obtained by differentiating the BSE signal waveform (X, I). A discontinuous point of the BSE differential signal waveform occurs at an interface between layers of different materials, and this discontinuous point is an interface coordinate XINT in the X direction. In obtaining the interface coordinate XINT, high-level differentiation may be used so as to react sharply, or other signal processing of determining a discontinuity of a slope of the BSE signal intensity from the side wall may be performed.

A method of calculating an interface depth hint (distance from the upper surface of the pattern) and a dimension d thereof by using a BSE signal intensity I_{INT} at the interface corresponding to the interface coordinate X_{INT}, the acquired attenuation coefficient μ₁ of the material 1 and attenuation coefficient μ₂ of the material 2 will be described with reference to FIG. 7B. The dimension d can be obtained based on a difference between X coordinates of two points of the BSE signal waveform 711 having the BSE signal intensity I_{INT} On the other hand, a BSE relative signal intensity nI_{INT} at the interface can be represented by (Equation 2). Here, the BSE relative signal intensity nI is a signal intensity obtained by normalizing the BSE signal intensity on the upper surface of the pattern as 1 and normalizing the BSE signal intensity on the bottom surface of the pattern as 0, and is a ratio of a contrast between an interface position and the bottom surface position of the pattern to a contrast between the upper surface position and the bottom surface position of the pattern. In addition, a depth of the entire pattern is set to H.

$$\begin{matrix}[ Math . 2 ] & \\ {nI}_{{h}_{int}} = \frac{{e}^{- {µ}_{1} {h}_{int}} - {e}^{- {µ}_{2} H}}{{e}^{- {µ}_{1} 0} - {e}^{- {µ}_{2} H}} & ( Equation 2 )\end{matrix}$$

Thereby, a ratio of the interface depth hint to the total depth H can be obtained. Although the details are omitted here, a BSE image is acquired by obliquely emitting the primary electron beam on the sample surface, and the total depth H can be obtained based on a relationship between a tilt angle of the primary electron beam and a magnitude of a positional deviation of the bottom surface of the hole in a BSE image acquired by emitting the primary electron beam perpendicular to the sample surface and the BSE image acquired by obliquely emitting the primary electron beam. The interface depth hint can be obtained by obtaining an absolute value of the total depth H.

A measurable depth is not limited to the interface depth, and a dimension and a depth at any position can be obtained. Alternatively, the cross-sectional shape can be obtained by continuously obtaining the dimension and the depth. Thus, a pattern depth h at any position can be calculated using (Equation 3).

$$\begin{matrix}[ Math . 3 ] & \\ {nI}_{h} = \frac{{e}^{- {µ}_{*} h} - {e}^{- {µ}_{2} H}}{{e}^{- {µ}_{1} 0} - {e}^{- {µ}_{2} H}} & ( Equation 3 )\end{matrix}$$

Here, an attenuation coefficient μ* is the attenuation coefficient μ₁ when a desired depth is located above the interface, and is the attenuation coefficient μ₂ when the desired depth is located below the interface.

A cross-section in the X direction has been described above, but it is also possible to obtain cross-section information in a plurality of orientations by changing the orientation in which the BSE signal intensity is extracted, and it is also possible to obtain a three-dimensional model by integrating the cross-section information in a large number of orientations.

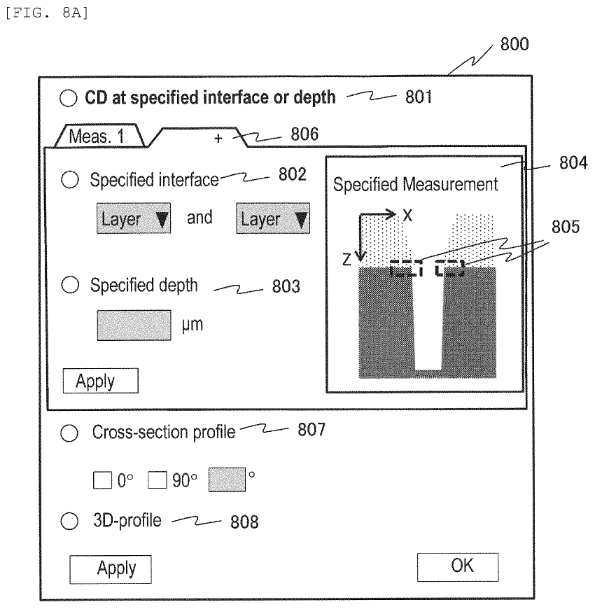

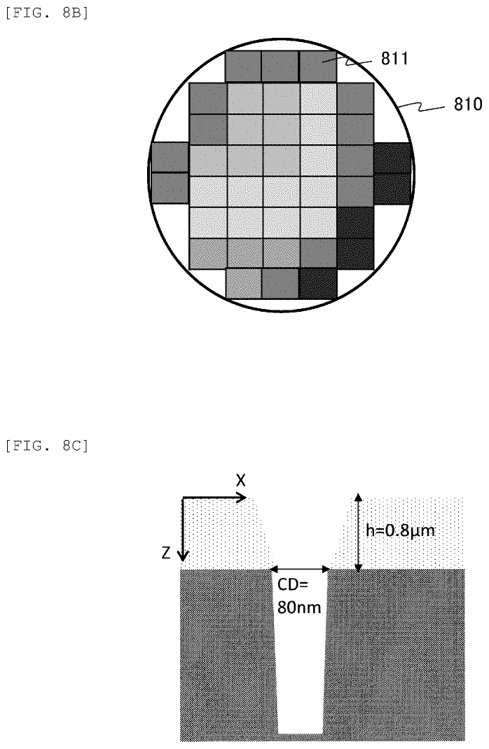

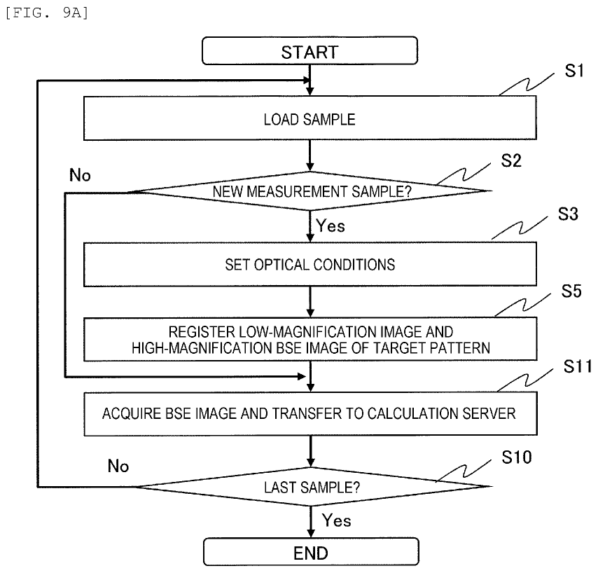

FIG. 8A shows an example of a GUI 800 for executing step S8 (item setting of shape measurement) in the sequence shown in FIG. 3. A dimension at a measurement position specified by a measurement position specification unit 801 is measured. In order to specify the measurement position, an interface specification unit 802 configured to specify an interface between the layers constituting the pattern and a depth specification unit 803 configured to instruct dimension measurement at a specific depth are provided. At this time, it is desirable to display the cross-section information on a pattern display unit 804 and display the specified measurement position by using a cursor 805. In this case, the cursor 805 is moved by the user such that the measurement position can be specified based on the cross-section information. In addition, the measurement position may be specified by a side wall angle on the cross-section profile, a maximum dimension, and a depth located at the maximum dimension, and the like. Further, the measurement position specification unit 801 makes it possible to measure a plurality of positions for one pattern by adding a tag 806. Furthermore, an orientation of the cross-section to be measured can be specified by an orientation specification unit 807, and when a 3D profile selection unit 808 is selected, it is possible to perform measurement in a plurality of orientations and obtain a three-dimensional model.

An example of an output screen of a shape measurement result in the pattern measurement system according to the present embodiment will be described. FIG. 8B is an example of an output screen that displays a wafer-level variation of the measurement target pattern. A square in a wafer map 810 represents a region (for example, a chip) 811 in which each measured pattern is present. For example, if a measured shape is appropriate, the square is displayed in a light color, and if a degree of deviation from an appropriate value is large, the square is displayed in a dark color. Thus, it is possible to display the wafer-level variation in a list by mapping and displaying measurement results at different locations on the wafer.

Further, if the user wants to know the details of the measurement results, a specific region is specified on the wafer map 810, and a dimensional value measurement result, depth (height) information, cross-section profile information, three-dimensional profile information, and the like obtained from the captured image of the measurement target pattern are displayed as shown in FIG. 8C. In addition, it is also possible to display, in a map, a location where a measured value exceeds a specified threshold value range based on a design value. The user can efficiently obtain information by performing such various displays.

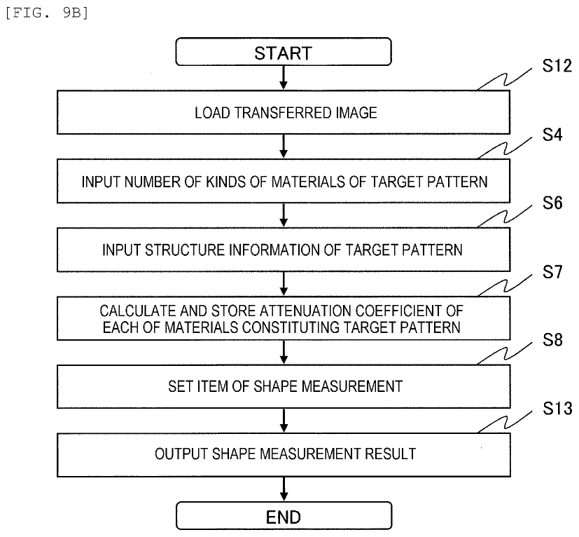

FIG. 1 shows an example of connecting the SEM to the calculation server 22 via the network 21, and FIGS. 9A and 9B show a flow in which an image is acquired and stored by the SEM and is transferred to the connected calculation server 22, and the calculation server 22 creates a measurement recipe and measures the 3D profile of the sample offline. The steps common to those in FIG. 3 are indicated by the same reference numerals as those in FIG. 3, and the duplicated explanation will be omitted. FIG. 9A shows a flow executed by the control unit 16 of the SEM. The SEM main body exclusively acquires an image necessary for measurement. When there is no measurement recipe for the measurement target pattern, the acquired image is transferred to the calculation server 22 together with an image for obtaining the attenuation coefficient μ (step S11). In addition, when a secondary electron image is acquired together with the BSE image, the secondary electron image is also transferred to the calculation server 22.

FIG. 9B shows a flow executed by the calculation server 22. The image transferred from the SEM connected to the network is loaded (step S12). When it is necessary to set a measurement recipe for the transferred image, steps S4 to S8 are executed for the low-magnification image and the high-magnification BSE image included in the transferred image, and the measurement recipe is set. According to the set measurement recipe, the 3D profile of the measurement target pattern is measured based on the BSE image acquired in step S11 by the SEM, and the shape measurement result is output to a display unit provided in the calculation server 22 or the like (step S13). In addition, when the measurement recipe is already present, only the BSE image acquired in step S11 is transferred from the SEM, so that the 3D profile of the measurement target pattern is measured according to the existing measurement recipe, and the shape measurement result is output (step S13).

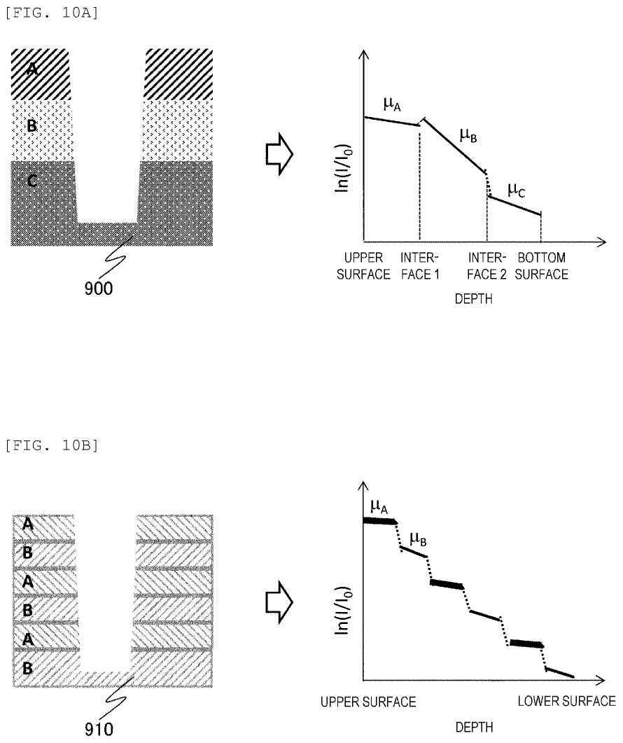

Although the present embodiment has been described by taking a sample obtained by stacking two kinds of materials as an example, there is no limitation on the number of layers constituting the pattern for the measurement target pattern. FIG. 10A shows a pattern formed on a sample 900 obtained by stacking two or more kinds of materials and a BSE signal intensity (ln (I/I₀)) thereof. FIG. 10B shows a pattern formed on a sample 910 obtained by alternately stacking a material A and a material B and a BSE signal intensity (ln (I/I₀)) thereof. There is no limit to the number of layers. In each case, an interface between materials is clearly indicated by the BSE signal intensity, and the 3D profile can be effectively measured by the measurement method of the present embodiment.

In contrast, the interface between different materials may be obscured. The first case is a case where atomic numbers and densities of a first material and a second material forming two adjacent layers are similar. In this case, attenuation coefficients of the two materials are similar, and it is difficult to separate the two materials. The second case is a case where a film thickness is thin. When a film thickness of a layer is thin and a distance traveled until the electron is scattered once in the sample involves a plurality of layers of materials, even when attenuation coefficients of the materials are significantly different from each other, the interface cannot be clearly indicated. When a difference in the attenuation coefficients with respect to the height of the side wall cannot be distinguished in this way, it is preferable to treat the layers as one layer and measure the 3D profile.

The invention has been described above with reference to the drawings. However, the invention should not be interpreted as being limited to description of the embodiments described above, and the specific configuration of the invention can be changed without departing from the spirit or gist of the invention. That is, the invention is not limited to the described embodiments, and may include various modifications. The described embodiments are described in detail in the configuration in order to clearly describe the invention, but the invention is not necessarily limited to an embodiment that includes all the configurations that have been described. In addition, a part of the configuration of each embodiment can be added to, deleted from, or replaced with the other configurations as long as no conflict arises.

Further, the position, size, shape, range, etc. of each configuration shown in the drawings and the like may not represent the actual position, size, shape, range, etc. so as to facilitate understanding of the invention. Therefore, the invention is not limited to the position, size, shape, range, etc. disclosed in the drawings and the like.

Furthermore, the embodiments show the control line and information line considered as necessary for the explanation, and all the control lines and information lines on the product are not always shown. For example, all of the configurations maybe mutually connected.

Moreover, the configurations, functions, processing units, processing means, and the like described in the present embodiments may partially or entirely be implemented by hardware by, for example, designing in the form of an integrated circuit. Alternatively, the configurations, functions, processing units, processing means, and the like may partially or entirely be implemented by program codes of software. In this case, a storage medium on which the program codes are recorded is provided to a computer, and a processor that the computer is provided with reads the program codes stored on the storage medium. In this case, the program codes themselves read from the storage medium realize the functions according to the embodiments mentioned above, and the program codes themselves and the storage medium storing the program codes constitute the invention.

### REFERENCE SIGN LIST

1 electron optical column

2 sample chamber

3 electron gun

3a ideal optical axis

4 condenser lens

5, 6 deflector

7 objective lens

8 first electron detector

9 second electron detector

10 wafer

11 XY stage

12, 13 amplifier

14 electron optical system control unit

15 stage control unit

17 image processing unit

18 calculation unit

19 storage unit

20 system control unit

21 network

22 calculation server

200, 900, 910 sample

201 interface

205 hole

211, 212, 213 primary electron beam

221, 222, 223 BSE

230 BSE signal intensity

400, 800 GUI

401 optical condition input unit

402 measurement target pattern registration unit

403 material constituent input unit

404 top-view image registration unit

405 low-magnification image registration unit

406, 409 imaging condition selection box

407 low-magnification image

408 high-magnification BSE image registration unit

410, 510 high-magnification BSE image

411 structure input unit

412 cross-sectional image input unit

413 design data input unit

414 cross-section information input unit

415 manual input unit

416 layer-based input box

417 material selection unit

418 user definition unit

419 film thickness input unit

420 attenuation coefficient display unit

500 cross-sectional image

501 cross-section profile

502 inclined portion

511 BSE profile

512 orientation

513 upper surface position

514 bottom surface position

515 BSE signal waveform

521 BSE profile

522 BSE signal waveform

523, 524 range

601 binarized image

602 individual unit

701 BSE differential signal waveform

711 BSE signal waveform

801 measurement position specification unit

802 interface specification unit

803 depth specification unit

804 pattern display unit

805 cursor

806 tag

807 orientation specification unit

808 3D profile selection unit

810 wafer map

811 region

1. A pattern measurement system configured to measure a 3D profile of a pattern formed in stacked layers comprising a plurality of different materials, the pattern measurement system comprising:
a storage unit configured to store, for each of materials constituting the pattern, an attenuation coefficient of the materials which indicating a probability of an electron being scattered at a unit distance in the material; and
a calculation unit configured to extract an interface position where different materials are in contact with each other, an upper surface position and a bottom surface position of the pattern in a BSE image created by detecting a backscattered electron emitted by scanning the pattern with a primary electron beam, and calculate a depth from the upper surface position to an specified position of the pattern, wherein
the calculation unit calculates the depth from the upper surface position to the specified position of the pattern based on a ratio of a contrast between the specified position and the bottom surface position of the pattern to a contrast between the upper surface position and the bottom surface position of the pattern in the BSE image, and an attenuation coefficient of a material at the bottom surface position of the pattern and an attenuation coefficient of a material at the specified position of the pattern, which are stored in the storage unit.

2. The pattern measurement system according to claim 1, wherein
the calculation unit extracts, the BSE signal profile represented by a backscattered electron signal intensity from a side wall of the pattern along a predetermined direction in the BSE image, and a discontinuous point of a differential signal profile of the BSE profile is extracted and determined as the interface position.

3. The pattern measurement system according to claim 1, wherein
the calculation unit calculates a depth of the bottom surface position with respect to the upper surface position of the pattern based on a relationship between a tilt angle of the primary electron beam and a positional deviation amount between a bottom surface of the pattern in an inclined BSE image and a bottom surface of the pattern in the BSE image, which is created by detecting a backscattered electron emitted by scanning the pattern with the primary electron beam tilted with respect to a surface of the sample.

4. The pattern measurement system according to claim 1, wherein
the sample is a wafer, and
a plurality of variations in the 3D profile of the pattern formed on the wafer are displayed on a wafer map.

5. A pattern measurement system configured to measure a 3D profile of a pattern formed on a sample obtained by stacking a plurality of different materials, the pattern measurement system comprising:
an electron optical system configured to irradiate the sample with a primary electron beam;
a first electron detector configured to detect a secondary electron emitted by scanning the pattern with the primary electron beam;
a second electron detector configured to detect a backscattered electron emitted by scanning the pattern with the primary electron beam;
an image processing unit configured to form an image based on a detection signal of the first electron detector or the second electron detector; and
a calculation unit configured to compare a cross-section profile of a side wall of the pattern extracted from a cross-sectional image of the pattern and a BSE profile which indicates a backscattered electron signal intensity from the side wall of the pattern along a predetermined direction and which is extracted from a first BSE image formed by the image processing unit based on the detection signal of the second electron detector, distinguish the BSE profile according to the pattern formed in each of the materials, and obtain an attenuation coefficient of the material based on a relationship between a depth from an upper surface position of the pattern and a backscattered electron signal intensity in the distinguished BSE profile.

6. The pattern measurement system according to claim 5, wherein
the cross-sectional image is design data of the pattern or a cross-sectional image of the pattern obtained by imaging by at least one of a scanning electron microscope, a focused ion beam microscope, a scanning transmission electron microscope, and an atomic force microscope.

7. The pattern measurement system according to claim 5, wherein
the image processing unit forms a first secondary electron image based on the detection signal of the first electron detector, which is acquired at the same time as the detection signal of the second electron detector that forms the first BSE image, and
the calculation unit specifies the upper surface position of the pattern by using the first secondary electron image.

8. The pattern measurement system according to claim 5, further comprising:
a storage unit configured to store, for each of the materials constituting the pattern, an attenuation coefficient indicating a probability that the material having a predetermined density and an electron are scattered at a unit distance in the material when the material in which the pattern does not exist is irradiated with the primary electron beam at a predetermined acceleration voltage, wherein
the image processing unit forms a second secondary electron image having a lower magnification than that of the first BSE image based on the detection signal of the first electron detector, and
the calculation unit obtains, an attenuation coefficient of each of the materials constituting the pattern according to the attenuation coefficient stored in the storage unit and a pattern density being calculated according to the second secondary electron image of the pattern formed in the material.

9. The pattern measurement system according to claim 5, wherein
the calculation unit extracts an upper surface position, and a bottom surface position, and an interface position of different materials, from the pattern in a second BSE image being created by detecting the backscattered electron emitted by scanning the pattern with the primary electron beam, and calculates a depth from the upper surface position to an specified position of the pattern according to a ratio of a contrast between the specified position and the bottom surface position of the pattern to a contrast between the upper surface position and the bottom surface position of the pattern in the second BSE image, and an attenuation coefficient of a material at the bottom surface position of the pattern and an attenuation coefficient of a material at the specified position of the pattern, the second BSE image.

10. The pattern measurement system according to claim 9, wherein
the calculation unit extracts, from the second BSE image, a BSE signal profile indicating a backscattered electron signal intensity from a side wall of the pattern along a predetermined direction, and extracts a discontinuous point from a differential signal profile of the BSE signal profile to determine the discontinuous point as the interface position.

11. The pattern measurement system according to claim 9, wherein
the calculation unit calculates a depth of the bottom surface position with respect to the upper surface position of the pattern based on a relationship between a tilt angle of the primary electron beam and a positional deviation amount between a bottom surface of the pattern using an tilted BSE image and a bottom surface of the pattern using the second BSE image. The tilted BSE image being created by detecting a backscattered electron emitted by scanning the pattern with the primary electron beam tilted with respect to a surface of the sample.

12. A pattern measurement method of measuring a 3D profile of a pattern formed in a sample obtained by stacking a plurality of different materials, the pattern measurement method comprising:
previously storing, for each of materials constituting the pattern, an attenuation coefficient indicating a probability of an electron being scattered at a unit distance in the material; and
extracting an interface position where different materials are in contact with each other, an upper surface position, and a bottom surface position of the pattern in a BSE image created by detecting a backscattered electron emitted by scanning the pattern with a primary electron beam, and calculating a depth from the upper surface position to an specified position of the pattern according to a ratio of a contrast between the specified position and the bottom surface position of the pattern to a contrast between the upper surface position and the bottom surface position of the pattern in the BSE image, an attenuation coefficient of a material at the bottom surface position of the pattern, and an attenuation coefficient of a material at the specified position of the pattern.

13. The pattern measurement method according to claim 12, further comprising:
extracting, from the BSE image, a BSE signal profile indicating a backscattered electron signal intensity from a side wall of the pattern along a predetermined direction, and extracting a discontinuous point of a differential signal profile of the BSE signal profile as the interface position.

14. The pattern measurement method according to claim 12, further comprising:
calculating a depth of the bottom surface position with respect to the upper surface position of the pattern based on a relationship between a tilt angle of the primary electron beam and a positional deviation amount between a bottom surface of the pattern in an tilted BSE image and a bottom surface of the pattern in the BSE image, the tilted BSE image being created by detecting a backscattered electron emitted by scanning the pattern with the primary electron beam tilted respect to a surface of the sample
